(19) United States
(12) Patent Application Publication
(10) Pub. No.: US 2018/0223434 A1
(43) Pub. Date: Aug. 9, 2018

(54) VAPOR GROWTH APPARATUS, AND VAPOR GROWTH METHOD

(71) Applicant: NuFlare Technology, Inc., Kanagawa (JP)

(72) Inventors: Hideki ITO, Kanagawa (JP); Takanori HAYANO, Kanagawa (JP)

(21) Appl. No.: 15/940,032

(22) Filed: Mar. 29, 2018

Related U.S. Application Data
(63) Continuation of application No. PCT/JP2016/079067, filed on Sep. 30, 2016.

(30) Foreign Application Priority Data
Oct. 2, 2015 (JP) 2015-196919

(51) Int. Cl. C23C 16/52; C23C 16/458; C30B 25/12; C30B 25/16; G01B 11/14; H01L 21/02; H01L 21/687; H01L 21/67; H01L 21/66

(52) U.S. Cl. CPC C23C 16/52; C23C 16/4584; C30B 25/12; C30B 25/165; G01B 11/14; H01L 22/20; H01L 21/0254; H01L 21/0262; H01L 21/68764; H01L 21/67259; H01L 21/67288; H01L 21/02381

(57) ABSTRACT

A vapor growth apparatus has a reaction chamber, a gas supply part to supply a gas to the reaction chamber, a heater to heat the substrate from a surface opposite to a film growth surface of the substrate, an irradiation part to emit an optical signal to the film growth surface, a light receiving part to receive the reflected optical signal, a first light receiving range determination part to determine whether a light receiving position of the optical signal in the light receiving part is out of a predetermined first light receiving range, and a position deviation detection part to judge that the substrate has caused position deviation, a rotation part to rotate the substrate via a susceptor, a purge gas supply part to supply a purge gas into the rotation part, and a control part to control a supply amount of the purge gas.

### CROSS REFERENCE TO RELATED APPLICATIONS

This application is based upon and claims the benefit of priority from the prior Japanese Patent Application No. 2015-196919, filed on Oct. 2, 2015, the entire contents of which are incorporated herein by reference.

### FIELD

The present embodiment relates to a position deviation detection device, a vapor growth apparatus, and a position deviation detection method.

### BACKGROUND

An epitaxial growth technique for growing a single crystal thin film on a single crystal substrate, such as a silicon substrate, is used for manufacturing an electronic device using a compound semiconductor, such as an LED (light emitting diode) or GaN.

In a vapor growth apparatus used in the epitaxial growth technique, a wafer is placed inside a film formation chamber kept in a normal pressure or a reduced pressure. Then, when a gas serving as a raw material for forming a film is supplied into the film formation chamber while this wafer is heated, thermal decomposition reaction and hydrogen reduction reaction of the raw material gas occur on a surface of the wafer, and an epitaxial film is formed on the wafer (see JP 2009-231652 A).

Since a temperature and a raw material gas are different for every film formed on a wafer, in some cases, the wafer may be warped in the middle of film formation due to a difference in lattice constants. An amount of warpage of the wafer varies depending on a temperature, a kind of raw material gas, and a pressure.

Accordingly, a technique for measuring a warpage amount of a wafer and adjusting a film formation condition according to the measured warpage amount has been proposed.

Further, a wafer is placed on susceptor within a chamber of a vapor growth apparatus. When the wafer is placed deviated from a desired position on the susceptor, a uniform epitaxial film cannot be formed on the wafer. For example, when the wafer is placed in a direction inclined to the susceptor for some reason, in a case where the film formation is performed while the wafer is rotated at a high speed, it is possible that the wafer flies out from the susceptor, collides with an inner wall etc. of the chamber, and breaks the chamber.

Furthermore, even if the wafer is placed at the desired position on the susceptor, when a pressure below the wafer is higher than a pressure above the wafer, the wafer is floated from the susceptor. When the wafer is rotated at a high speed in this state, it is also possible that the wafer flies out from the susceptor and breaks the chamber.

The present embodiment provides a position deviation detection device, a vapor growth apparatus, and a position deviation detection method capable of accurately detecting position deviation of a measuring object, such as a wafer.

One embodiment provides a position deviation detection device including: an irradiation part to emit an optical signal to a measuring object; a light receiving part to receive the optical signal reflected by the measuring object; a first light receiving range determination part to determine whether a light receiving position of the optical signal in the light receiving part is out of a predetermined first light receiving range; and a position deviation detection part to judge that the measuring object has caused position deviation, when the first light receiving range determination part determines that the light receiving position is out of the first light receiving range.

Further, the position deviation detection device may include: a second light receiving range determination part to determine whether the light receiving position of the optical signal in the light receiving part is within a second light receiving range included in the first light receiving range; and a warpage amount detection part to detect a warpage amount of the measuring object according to the light receiving position within the second light receiving range, when the second light receiving range determination part determines that the light receiving position of the optical signal is within the second light receiving range.

Further, another embodiment provides a vapor growth apparatus including: a reaction chamber to cause a vapor growth reaction to a substrate; a gas supply part to supply a gas to the reaction chamber; heating means to heat the substrate from a surface opposite to a film growth surface of the substrate; an irradiation part to emit an optical signal to the film growth surface; a light receiving part to receive the optical signal reflected by the film growth surface; a first light receiving range determination part to determine whether a light receiving position of the optical signal in the light receiving part is out of a predetermined first light receiving range; and a position deviation detection part to judge that the substrate has caused position deviation, when the first light receiving range determination part determines that the light receiving position is out of the first light receiving range.

Further, the heating means may be disposed inside the reaction chamber. The vapor growth apparatus may further have: a rotation part to rotate the substrate via a susceptor; a purge gas supply part to supply a purge gas into the rotation part; and a control part to control a supply amount of the purge gas. The control part may detect a swing of an output signal in the position deviation detection part and perform control so as to reduce a flow rate of the purge gas.

Further, another embodiment provides a position deviation detection method including: a step of emitting an optical signal to a measuring object; a step of receiving the optical signal reflected by the measuring object; a step of determining whether a light receiving position of the optical signal in the light receiving part is out of a predetermined first light receiving range; and a step of judging that the measuring object has caused position deviation, when it is determined that the light receiving position is out of the first light receiving range.

### BRIEF DESCRIPTION OF THE DRAWINGS

FIG. 1 is a diagram illustrating a schematic configuration of a vapor growth apparatus according to one embodiment.

FIG. 2A is a diagram illustrating an example in which a wafer W does not cause position deviation.

FIG. 2B is a diagram illustrating an example in which the wafer W causes position deviation.

FIG. 3 is a block diagram illustrating an example of an internal configuration of a position deviation detection device.

FIG. 4 is a diagram illustrating a first light receiving range set on a light receiving surface of a first position detection element.

FIG. 5 is a diagram illustrating a schematic configuration of a vapor growth apparatus 1 according to a second embodiment.

### DETAILED DESCRIPTION

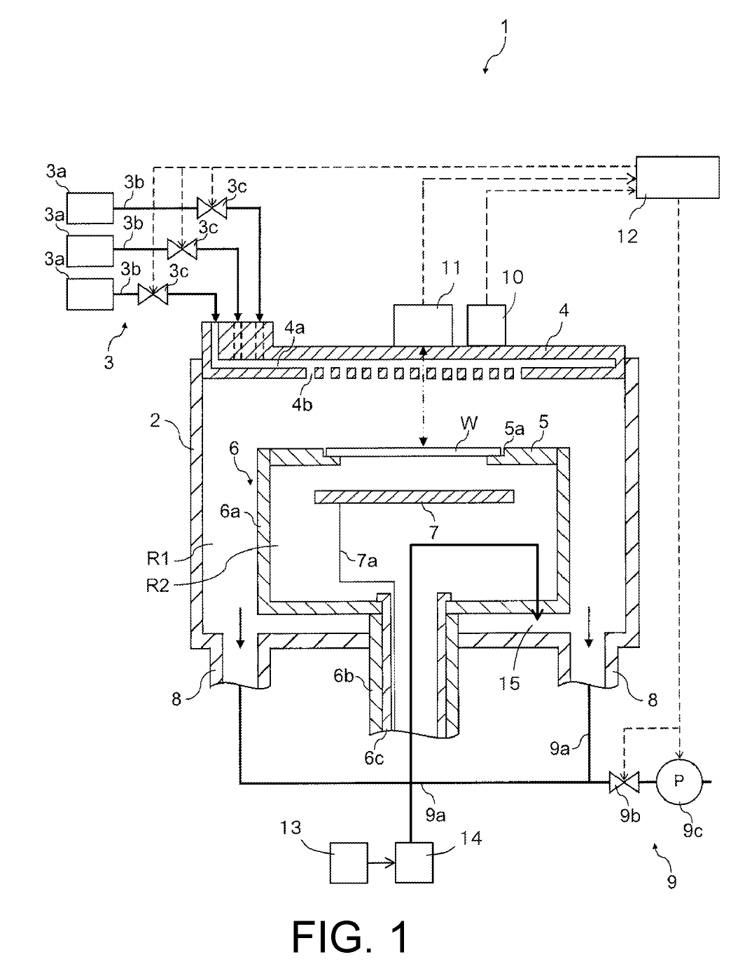

Hereinafter, a present embodiment is described with reference to the drawings. FIG. 1 is a diagram illustrating a schematic configuration of a vapor growth apparatus 1 according to one embodiment. In the present embodiment, a silicon substrate, or more specifically a silicon wafer (hereinafter simply referred to as a wafer) W is used as a substrate on which film formation processing is performed, and an example in which a plurality of films is laminated on this wafer W is described.

A vapor growth apparatus 1 in FIG. 1 includes a chamber 2 to perform film formation on the wafer W, a gas supply part 3 to supply a raw material gas to the wafer W within this chamber 2, a row material release part 4 located at a top of the chamber 2, a susceptor 5 to support the wafer W within the chamber 2, a rotation part 6 to hold and rotate this susceptor 5, a heater 7 to heat the wafer W, a gas discharge part 8 to discharge a gas within the chamber 2, an exhaust mechanism 9 to exhaust the gas from this gas discharge part 8, a radiation thermometer 10 to measure a temperature of the wafer W, a position deviation detection device 11 to detect position deviation of the wafer W, a control part 12 to control each of the parts, a purge gas supply part 13, a purge gas control part 14, and a purge gas discharge port 15.

The chamber 2 has a shape capable of housing the wafer W as a film formation object (for example, a cylindrical shape). The susceptor 5, the heater 7, a portion of the rotation part 6, and the like are accommodated inside the chamber 2.

The gas supply part 3 has a plurality of gas storage parts 3a to individually store a plurality of gasses, a plurality of gas pipes 3b to connect these gas storage parts 3a and the raw material release part 4, and a plurality of gas valves 3c to adjust flow rates of the gases flowing in these gas pipes 3b. Each of the gas valves 3c is connected to the corresponding gas pipe 3b. The plurality of gas valves 3c is controlled by the control part 12. An actual pipe arrangement can employ a plurality of configurations, such as coupling of a plurality of gas pipes, branching of one gas pipe to a plurality of gas pipes, or a combination of branching and coupling of gas pipes.

The raw material gas supplied from the gas supply part 3 is released into the chamber 2 through the raw material release part 4. The raw material gas (a process gas) released into the chamber 2 is supplied onto the wafer W. With this configuration, a desired film is formed on the wafer W. Note that a kind of raw material gas to be used is not particularly limited. The raw material gas can be changed variously according to a kind of film to be formed.

A shower plate 4a is provided on a bottom surface side of the raw material release part 4. This shower plate 4a can be formed of a metallic material, such as stainless steel or an aluminum alloy. The gases from the plurality of gas pipes 3b are mixed within the raw material release part 4 and then supplied into the chamber 2 through gas jetting ports 4b of the shower plate 4a. Note that a plurality of gas flow passages may be provided in the shower plate 4a to supply the plural kinds of gasses in a separated state to the wafer W within the chamber 2.

A structure of the raw material release part 4 should be selected in consideration of uniformity of a formed film, raw material efficiency, reproducibility, manufacturing cost, and the like. However, the structure is not particularly limited if it satisfies these demands, and a well-known structure can be used as appropriate.

The susceptor 5 is provided at a top of the rotation part 6 and has a structure that supports the wafer W by placing the wafer W in a counterbore provided on an inner peripheral side of the susceptor 5. Note that in the example in FIG. 1, the susceptor 5 is formed in an annular shape having an opening at a center. However, the susceptor 5 may be formed in a substantially flat plate shape having no opening.

The heater 7 is a heating part to heat the susceptor 5 and/or the wafer W. The heater 7 is not particularly limited if it satisfies demands, such as durability and a capacity to heat a heating object at a desired temperature and temperature distribution. Specifically, a heating method includes a resistance heating, lamp heating, induction heating, and the like.

The exhaust mechanism 9 exhausts the reacted raw material gas from inside of the chamber 2 via the gas discharge part 8 and controls the inside of the chamber 2 at a desired pressure by action of an exhaust valve 9b and a vacuum pump 9c.

The radiation thermometer 10 is provided on an upper surface of the raw material release part 4. The radiation thermometer 10 irradiates the wafer W with light from a light source (not illustrated), receives reflected light from the wafer W, and measures intensity of the reflected light of the wafer W. Further, the radiation thermometer 10 receives heat radiation light from a film growth surface Wa of the wafer W and measures intensity of the heat radiation light. FIG. 1 illustrates only one radiation thermometer 10. However, a plurality of radiation thermometers 10 may be disposed on the upper surface of the raw material release part 4 to measure temperatures at a plurality of places (for example, an inner peripheral side and an outer peripheral side) on the film growth surface Wa of the wafer W.

A light transmission window is provided on the upper surface of the raw material release part 4. The light from the light source of the radiation thermometer 10 or the position deviation detection device 11, which will be described below, and the reflected light or the heat radiation light from the wafer W pass through this light transmission window. The light transmission window can have any shape, such as a slit shape, a rectangular shape, or a round shape. A member that is transparent to a wavelength range of light measured by the radiation thermometer 10 and the position deviation detection device 11 is used for the light transmission window. When a temperature ranging from a room temperature to about 1500° C. is measured, it is preferable to measure a wavelength of light ranging from a visible area to a near infrared area. In this case, quartz or the like is preferably used as the member of the light transmission window.

The control part 12 includes a computer (not illustrated) to control each of the parts in the vapor growth apparatus 1 in a centralized manner and a storage part (not shown) to store film formation processing information about film formation processing and various programs. Based on the film formation processing information and the various programs, the control part 12 controls the gas supply part 3, a rotation mechanism of the rotation part 6, the exhaust mechanism 9, and the like, and controls heating of the wafer W by the heater 7.

The purge gas supply part 13 supplies purge gas into the chamber 2 under control of the purge gas control part 14. The purge gas is an inert gas etc. for suppressing deterioration of the heater 7. The purge gas discharge port 15 is provided at a plurality of places at a bottom of the rotation part 6.

As described below, the position deviation detection device 11 detects position deviation of the wafer W placed on the susceptor 5. The position deviation herein indicates a case where the wafer W is disposed inclined to a wafer installation surface on the susceptor 5.

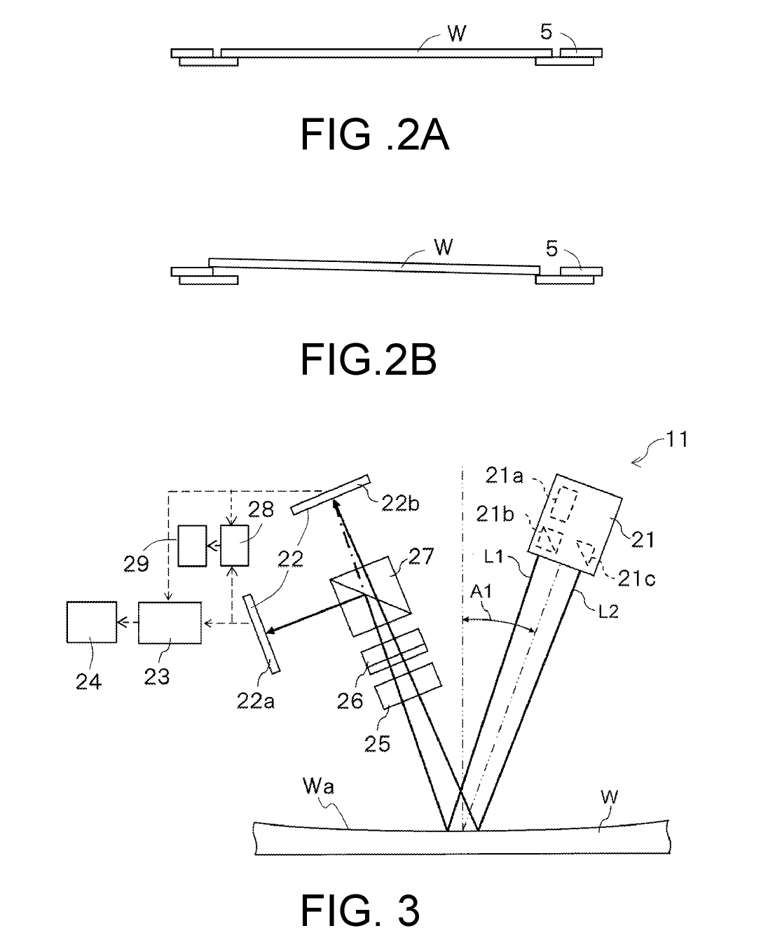

FIG. 2A illustrates an example in which the wafer W does not cause position deviation, and FIG. 2B illustrates an example in which the wafer W causes position deviation. As illustrated in FIG. 2B, when the wafer W runs on to an edge portion of the susceptor 5, the wafer W causes the position deviation. The position deviation as in FIG. 2B may be caused by deterioration of positioning accuracy when the wafer W is carried into the chamber 2 by a robot arm. Alternatively, the position deviation may be caused by changing a pressure condition in the chamber 2 after the wafer W is correctly placed on the susceptor 5

When film formation processing is performed on the wafer W while the wafer W causes the position deviation, it is difficult to accurately form a uniform film so that a film thickness becomes a desired value. Hence, in the present embodiment, when the position deviation detection device 11 detects the position deviation of the wafer W, it is assumed that the film formation processing is stopped and that the wafer W is collected (carried out) from the chamber 2.

FIG. 3 is a block diagram illustrating an example of an internal configuration of the position deviation detection device 11. The position deviation detection device 11 in FIG. 3 has an irradiation part 21, a light receiving part 22, a first light receiving range determination part 23, and a position deviation detection part 24. Moreover, the position deviation detection device 11 in FIG. 3 has an optical filter 25, a converging lens 26, and a course changing part 27. Furthermore, the position deviation detection device 11 in FIG. 3 may have a second light receiving range determination part 28 and a warpage amount detection part 29.

The irradiation part 21 emits an optical signal to the wafer W. It is desirable that the optical signals emitted from the irradiation part 21 be laser light beams whose phases and frequencies are matched. In the example in FIG. 3, the irradiation part 21 emits two laser light beams to the film growth surface Wa of the wafer W.

The irradiation part 21 has a light emitting part 21a, a polarized beam splitter 21b, and a mirror 21c. The polarized beam splitter 21b separates the laser light beams emitted from the light emitting part 21a into an S-polarized component and a P-polarized component. A laser light beam having the S-polarized component (hereinafter, a first laser light beam) L1 is made incident on the film growth surface Wa of the wafer W as it is. A laser light beam having the P-polarized component (hereinafter, a second laser light beam) L2 is reflected by the mirror 21c and made incident on the film growth surface Wa of the wafer W in a state in which the second laser light beam L2 is parallel to the first laser light beam L1. Note that travelling directions of the first laser light beam L1 and the second laser light beam L2 may not be parallel in a strict sense.

For example, incident positions of the first laser light beam L1 and the second laser light beam L2 on the film growth surface Wa of the wafer W are near a center of the film growth surface Wa. It is desirable that an incident angle A1 of each of the laser light beams L1, L2 be at least 20 degrees or less, as described below. Further, as the laser light beam, it is desirable to use a laser light beam having a wavelength of 700 nm or less, more preferably 600 nm or less (for example, 532 nm) so that an influence of light emitted from the red-heated wafer W is avoided, and for example, sensitivity of a silicon detection system is high, and an influence of heat radiation is small.

The optical filter 25 is provided between the wafer W and the course changing part 27 and on an optical path where the first laser light beam L1 and the second laser light beam L2 advance in parallel. The optical filter 25 cuts (eliminates) a light beam having a wavelength other than the wavelength of the first laser light beam L1 and the second laser light beam L2. For example, a monochromatic filter can be used for the optical filter 25. By providing this optical filter 25, a light beam having a wavelength other than the wavelength of each of the laser light beams L1 and L2 (green in the above-described example) is not made incident on position detection elements 22a and 22b, the influence of light emitted from the red-heated wafer W is avoided, and position detection accuracy can be improved.

The light receiving part 22 has a first position detection element 22a and a second position detection element 22b. For example, a semiconductor position sensing device (PSD) is used for the first position detection element 22a and the second position detection element 22b. The PSD calculates a centroid (a position) of distribution of incident laser light beams (a light quantity of a spot) and outputs the centroid as two electric signals (analog signals). The PSD has sensitivity to light in a visible light range. In the vapor growth apparatus 1 according to the present embodiment, the wafer W is red-heated, that is, emits red light. If the wafer W is only red-heated, since intensity of the laser light is overwhelmingly stronger, there is no problem if green laser light which is apart from the red is used at least. However, upon the film formation in the vapor growth apparatus 1 according to the present embodiment, timing when the laser light is hardly reflected is generated by interference between the film and the laser light. Since the intensity of the red-heated light exceeds the intensity of the reflected laser light, a position of the laser light reflected from the measuring object (the wafer W) on the position detection element 22a or 22b cannot be measured correctly or at all. In order to prevent this, it is desirable to provide the optical filter 25 which does not transmit light having a wavelength other than that of the laser light used in the present embodiment. Note that, besides the PSD, a solid state imaging element (a CCD, a

CMOS, or the like) can be used for the position detection element 22a or 22b.

Further, in order to remove an interference effect caused by the film formed on the above-described measuring object, it is also effective to use laser light having a wavelength absorbed by the formed film as the laser light of the present embodiment. More specifically, the laser light includes laser light having energy higher than that of a band gap of the formed film. When the formed film absorbs the laser light used in the present embodiment, the interference effect is reduced as the film is thicker, and the interference effect does not appear when a film thickness is a certain extent or more. For example, when GaN is used for film formation, the GaN has an absorption edge in an ultraviolet region (365 nm) at a room temperature. However, a band gap is reduced at a temperature of 700° C. or more, and the GaN absorbs light in a blue-violet region. Therefore, when the GaN grows at the temperature of 700° C. or more, the interference effect in the GaN can be reduced by using, for example, laser light having 405 nm in the present embodiment.

The converging lens 26 is provided between the wafer W and the course changing part 27 and on an optical path where the first laser light beam L1 and the second laser light beam L2 advance in parallel. This converging lens 26 converges the first laser light beam L1 on a light receiving surface of the first position detection element 22a and converges the second laser light beam L2 on a light receiving surface of the second position detection element 22b. A semi-cylindrical lens can be used for this converging lens 26.

The course changing part 27 separates the first laser light beam L1 and the second laser light beam L2 specular-reflected by the surface of the wafer W and changes the traveling directions into largely different directions. For example, the polarized beam splitter 21b (the second polarized beam splitter 21b) can be used for this course changing part 27. The first laser light beam L1 subjected to the course change travels in a direction of the first position detection element 22a, and the second laser light beam L2 travels in a direction of the second position detection element 22b. Note that an optical part, such as the mirror 21c, may be added between the course changing part 27 and the position detection element 22a or 22b to change an installation position of the position detection element 22a or 22b.

The first position detection element 22a is a one-dimensional position detection element that receives the first laser light beam L1 separated by the course changing part 27 and detects an incident position (a light receiving position). This first position detection element 22a is provided so that a normal direction of an element surface (the light receiving surface) is inclined within a range of 10 to 20 degrees from an optical axis of the first laser light beam L1.

The second position detection element 22b is a one-dimensional position detection element that receives the second laser light beam L2 separated by the course changing part 27 and detects an incident position (a light receiving position). As with the first position detection element 22a, this second position detection element 22b is provided so that a normal direction of an element surface (the light receiving surface) is inclined within a range of 10 to 20 degrees from an optical axis of the second laser light beam L2.

In this way, the normal directions of the light receiving surfaces of the light receiving part 22 including the first position detection element 22a and the second position detection element 22b are inclined with respect to the directions of the incident laser light beams, thereby preventing occurrence of an optical feedback in which the laser light beams reflected from the first and second position detection elements 22a, 22b are again returned to the above-described optical system. The optical feedback acts as noise to the reflected light originally required from the measuring object. By inclining the first and second position detection elements 22a, 22b as described above, the reflected light (the optical feedback) by the position detection element 22a or 22b is not made incident on the course changing part 27, and deterioration of position detection accuracy caused by the reflected light (the optical feedback) can be prevented.

The first light receiving range determination part 23 determines whether the incident position of the first laser light beam L1 detected by the first position detection element 22a and the incident position of the second laser light beam L2 detected by the second position detection element 22b are out of a predetermined first light receiving range.

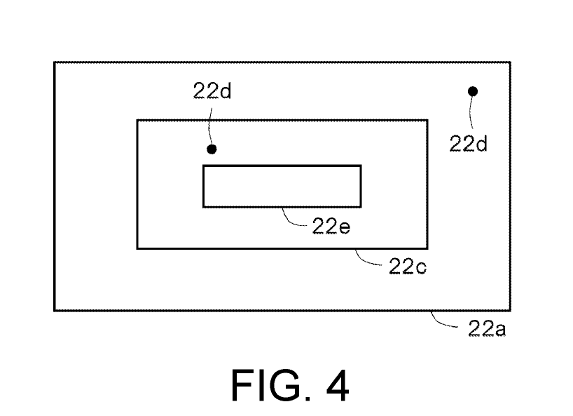

FIG. 4 is a diagram illustrating a first light receiving range 22c set on the light receiving surface of the first position detection element 22a. When the wafer W is placed at a desired position on the susceptor 5, the incident position of the first laser light beam L1 is always within the first light receiving range 22c. Meanwhile, when a bottom surface of the wafer W touches an edge of the susceptor 5 and the wafer W is disposed inclined to the susceptor 5, the first laser light beam L1 is made incident at a position out of the first light receiving range 22c.

FIG. 4 illustrates a case where a beam spot 22d of the first laser light beam is within the first light receiving range 22c and a case where the beam spot 22d is outside the first light receiving range 22c.

FIG. 4 illustrates the first light receiving range 22c of the first position detection element 22a. Similarly, the first light receiving range 22c is also set in the second position detection element 22b.

When an inclination angle of the wafer W to the wafer installation surface of the susceptor 5 is large, it is possible that the first laser light beam L1 and the second laser light beam L2 are not made incident on any of the first position detection element 22a and the second position detection element 22b.

In this case as well, the first light receiving range determination part 23 determines that the incident positions of the first laser light beam L1 and the second laser light beam L2 are out of the first light receiving range 22c.

When the first light receiving range determination part 23 determines that the incident positions of the first laser light beam L1 and the second laser light beam L2 are deviated from the first light receiving range 22c, the position deviation detection part 24 judges that the wafer W has caused position deviation.

When the position deviation detection part 24 detects the position deviation of the wafer W, the collection control part 12 performs control so that the film formation processing using the wafer W placed on the susceptor 5 is stopped, the rotation part 6 is rotated to a phase capable of conveying the wafer W, and the wafer W is carried out (collected) from the chamber 2. The wafer W carried out from the chamber 2 is discarded, for example. Alternatively, when position deviation of the wafer W is not detected until a previous image formation process, the wafer W may be once carried out from the chamber 2. After that, the wafer W may be repositioned on the susceptor 5 within the chamber 2 again to restart the film formation processing from a subsequent film formation process. Further, when the laser light beam is not detected by at least one of the first position detection element 22a and the second position detection element 22b, it is judged that abnormality, such as breakage of the wafer W, has caused, and conveyance of the wafer W is stopped. When fragments of the broken wafer W are left within the chamber 2, the fragments are collected.

The position deviation detection device 11 according to the present embodiment can be used for not only detecting position deviation of the wafer W but also detecting warpage of the wafer W. When the first light receiving range determination part 23 determines that the incident positions of the first laser light beam L1 and the second laser light beam L2 are not deviated from the first light receiving range 22c, the second light receiving range determination part 28 determines whether the incident positions of the first laser light beam L1 and the second laser light beam L2 are within a second light receiving range included in the first light receiving range 22c. As illustrated in FIG. 4, the second light receiving range is a range smaller than the first light receiving range 22c. Note that the second light receiving range may be the same range as the first light receiving range 22c.

When the second light receiving range determination part 28 determines that the incident positions of the first laser light beam L1 and the second laser light beam L2 are within the second light receiving range, the warpage amount detection part 29 detects a warpage amount of the wafer W according to the incident positions of the first laser light beam L1 and the second laser light beam L2 on the respective light receiving surfaces of the first position detection element 22a and the second position detection element 22b.

For example, the warpage amount detection part 29 calculates a difference between a displacement amount of the incident position of the first laser light beam L1 detected by the first position detection element 22a and a displacement amount of the incident position of the second laser light beam L2 detected by the second position detection element 22b. Then, the warpage amount detection part 29 calculates a curvature change amount of the wafer W from correlation between the calculated difference and individual optical path lengths of the first laser light beam L1 and the second laser light beam L2. A curvature before displacement can be converted into an absolute value of a radius of curvature by using a mirror for calibration, a substrate having no deformation, etc. as a reference.

A predetermined relational expression indicating the correlation, for example, includes a relational expression indicated as: (X1+X2)/2=w×Y×Z1, where displacement amounts on the first position detection element 22a and the second position detection element 22b respectively corresponding to the laser light beams L1 and L2 are represented by X1 and X2, individual optical path lengths of the laser light beams L1 and L2 are represented by Y1 and Y2, and a curvature change amount is represented by Z1. Herein, w is a distance between irradiation positions on the measuring object of the two laser light beams. Note that Y1 and Y2 are approximately equal and represented by Y, and signs of X1 and X2 are set so that displacements in center directions of the two laser light beams are the same.

Herein, it is not practical to strictly measure w and Y. On the other hand, w and Y are not greatly changed during measurement. Accordingly, in a simple relation indicated as: “Xtotal=C×Z1” (Xtotal=X1+X2), where a sum of the displacement amounts (that is, a geometric distance change between the two laser light beams) is proportional to the curvature, C can be determined by the mirrors for calibration 21c (two kinds) having known radii of curvature and applied. It is preferable that the radius of curvature of one of the two kinds be as infinite as possible (that is, a plane), and the radius of curvature of another be smallest among assumed radii of curvature. If possible, it is preferable that an intermediate radius of curvature be measured and formation of linearity in a measurement range (a case where a calibration curve is prepared for Z1) can be confirmed.

Further, it is preferable that the warpage amount detection part 29 fetches signals from the first position detection element 22a and the second position detection element 22b at predetermined timing. For example, the warpage amount detection part 29 fetches the signals from the first position detection element 22a and the second position detection element 22b simultaneously with fetching of a phase signal with periodic movement associating with the wafer W. The warpage amount detection part 29 calculates a curvature by using only a position signal within an arbitrary phase range of the periodic movement. For example, when the periodic movement is a rotation movement, while signal fetch timing is timing for every rotation of a motor of the rotation mechanism (a Z-phase pulse of the motor), the signals from the first position detection element 22a and the second position detection element 22b are fetched by synchronizing the signal fetch timing with rotation of the motor. The position signal may be information at one arbitrary point, or an average value in an arbitrary range. Further, it is preferable to integrate the information and the average value. When these are difficult, it is recommended that information of a plurality of periods is entirely fetched to take an average.

Note that detection of the warpage amount of the wafer W by the position deviation detection device 11 is optional. Further, when a warpage amount detector to detect a warpage amount of the wafer W is previously provided in the vapor growth apparatus 1, the warpage amount detector can be used as the position deviation detection device 11 according to the present embodiment.

In this way, in the first embodiment, the film growth surface Wa of the wafer W is irradiated with the first laser light beam and the second laser light beam, and position deviation of the wafer W is detected according to the incident positions on the first position detection element and the second position detection element of the first laser light beam and the second laser light beam reflected by the film growth surface Wa. With this configuration, the position deviation of the wafer W can be detected by a simple method.

Particularly, a warpage amount measurement device conventionally used to detect warpage of the wafer W can be immediately applied to the position deviation detection device 11 used for detecting the position deviation of the wafer W in the present embodiment. The incident positions on the first position detection element and the second position detection element of the first laser light beam and the second laser light beam when the warpage amount of the wafer W is measured are within a second light receiving range 22e that is smaller than the first light receiving range 22c when position deviation of the wafer W is judged. Hence, by setting the first light receiving range 22c that is larger than the second light receiving range 22e used when the warpage amount measurement device detects the warpage amount, position deviation of the wafer W can be detected by using the warpage amount measurement device.

In this way, since the position deviation detection device 11 can be configured using the warpage amount measurement device, the position deviation of the wafer W can be detected accurately without increasing equipment cost.

### Second Embodiment

In a second embodiment, a measure is taken against a trouble in which a wafer W flies out from a susceptor 5 caused by a pressure difference between above and below the wafer W placed on the susceptor 5.

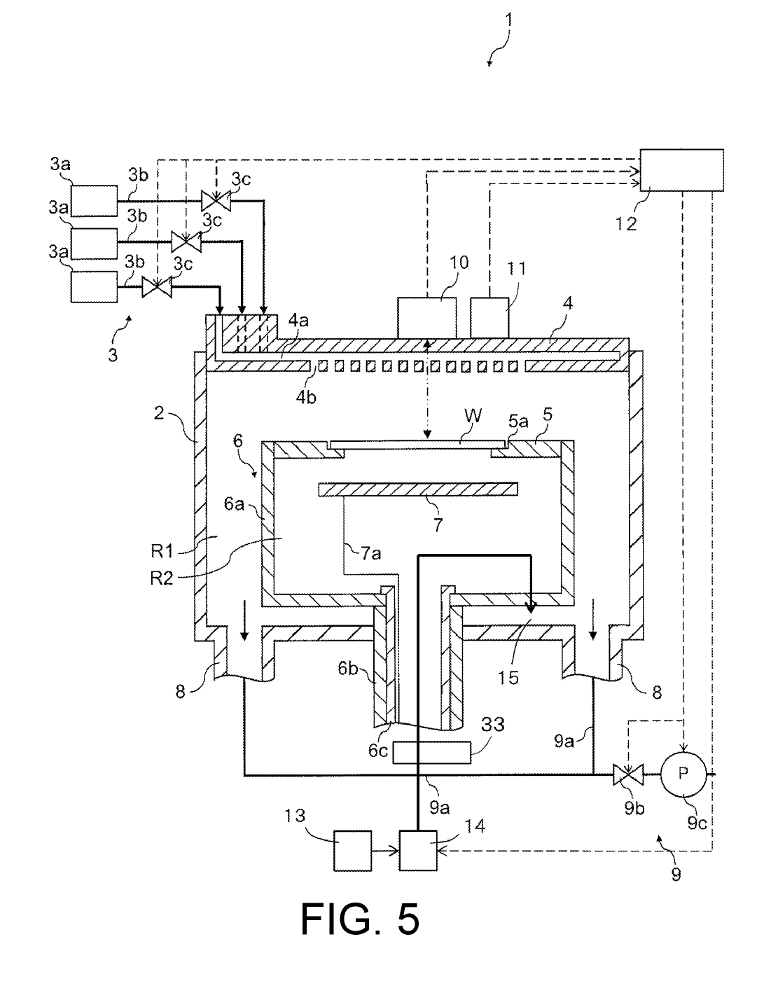

FIG. 5 is a diagram illustrating a schematic configuration of a vapor growth apparatus 1 according to the second embodiment. In the drawing, members that are common to those in FIG. 1 are denoted by the same signs, and differences are mainly described below.

A configuration of the vapor growth apparatus 1 in FIG. 5 is similar to that of the vapor growth apparatus 1 in FIG. 1. The second embodiment is different from the first embodiment in that a flow rate of a purge gas into a rotation part 6 is controlled by a control part 12 and a purge gas control part 14. A position deviation detection device 11 is similar to that in the first embodiment.

The purge gas, such as an inert gas, is supplied into the rotation part 6 to suppress deterioration of a heater. When film formation is performed on the wafer W, a temperature and a supply amount of a process gas vary according to a kind of a film to be formed. Accordingly, a pressure difference between above and below the wafer W may be generated in the middle of the film formation, and the wafer W may be floated.

Thus, when an output signal of the position deviation detection device 11 swings, the control part 12 and the purge gas control part 14 judge that the wafer W is floated and a pressure within the rotation part 6 is increased, thereby decreasing a supply amount of the purge gas. In this way, the position deviation detection device 11 according to the present embodiment has a function of a pressure determination part which determines whether a pressure below the wafer W is higher than a pressure above the wafer W by a predetermined value or more according to presence of a swing of the output signal of the position deviation detection device 11.

In this way, when the output signal swings, the flow rate of the purge gas is reset to a value to an extent that the wafer W is not floated from the susceptor 5. More specifically, since the wafer W is rotated at a high speed during the film formation, the flow rate is adjusted so that the wafer W is not floated from the susceptor 5 even at the high speed rotation.

This control prevents the pressure within the rotation part 6 from becoming higher than that within the chamber 2 by the predetermined value or more, and the wafer W is not floated from the susceptor 5. Hence, even when the wafer W is rotated at a high speed during the film formation processing, the wafer W does not fly out from the susceptor 5, and breakage of the chamber 2 etc. caused by the flying out of the wafer W can be prevented beforehand.

Note that there is a case where the pressure above the wafer W is higher than the pressure below the wafer W depending on a film formation condition. In this case, since the wafer W is pushed to the susceptor 5, there is no risk that the wafer W is floated from the susceptor 5.

In this way, in the second embodiment, when the output signal of the position deviation detection device 11 swings in the middle of the film formation, floating of the wafer W is detected, and the control part 12 and the purge gas control part 14 perform the processing in which the supply amount of the purge gas within the rotation part 6 is decreased to reduce the pressure. Accordingly, even when the wafer W is rotated at a high speed, the wafer W is not floated from the susceptor 5, and breakage of the wafer W itself, the chamber 2, etc. caused by position deviation of the wafer W can be prevented beforehand.

The first embodiment and the second embodiment described above can be implemented in combination. In other words, the position deviation detection device 11 may continuously monitor position deviation of the wafer W during film formation. When the output signal swings, the pressure within the rotation part 6 is reduced. When it can be judged that an amount of position deviation of the wafer W is large, the film formation processing may be stopped to collect the wafer W.

Although various embodiments have been described above, these embodiments have been presented by way of example and are not intended to limit a scope of the invention. These novel embodiments can be implemented in various other forms, and various omissions, replacements, and modifications can be made without departing from a gist of the invention. These embodiments and their variations are included in the scope and the gist of the invention and are included in the invention described in the claims and their equivalents. Reference Signs List

1. A vapor growth apparatus comprising:
a reaction chamber to cause a vapor growth reaction to a substrate;
a gas supply part to supply a gas to the reaction chamber;
a heater to heat the substrate from a surface opposite to a film growth surface of the substrate;
an irradiation part to emit an optical signal to the film growth surface;
a light receiving part to receive the optical signal reflected by the film growth surface;
a first light receiving range determination part to determine whether a light receiving position of the optical signal in the light receiving part is out of a predetermined first light receiving range; and
a position deviation detection part to judge that the substrate has caused position deviation, when the first light receiving range determination part determines that the light receiving position is out of the first light receiving range;
wherein the heater is disposed inside the reaction chamber,
the vapor growth apparatus further comprises:
a rotation part to rotate the substrate via a susceptor;
a purge gas supply part to supply a purge gas into the rotation part; and
a control part to control a supply amount of the purge gas,
wherein the control part detects a swing of an output signal in the position deviation detection part and performs control so as to reduce a flow rate of the purge gas.

2. The vapor growth apparatus according to claim 1, comprising:
a second light receiving range determination part to determine whether the light receiving position of the optical signal in the light receiving part is within a second light receiving range included in the first light receiving range; and
a warpage amount detection part to detect a warpage amount of the measuring object according to the light receiving position within the second light receiving range, when the second light receiving range determination part determines that the light receiving position of the optical signal is within the second light receiving range.

3. The vapor growth apparatus according to claim 1, comprising:
a susceptor on which the measuring object is placed,
wherein when the measuring object is disposed inclined to a placing surface of the susceptor, the position deviation detection part judges that the measuring object has caused position deviation.

4. The vapor growth apparatus according to claim 3, wherein
the susceptor comprises a counterbore to accommodate the measuring object, and
when at least a portion of the measuring object protrudes from the counterbore, the position deviation detection part judges that the measuring object has caused position deviation.

5. The vapor growth apparatus according to claim 3, comprising:
an optical filter to eliminate a wavelength component other than a wavelength component of the optical signal emitted from the irradiation part among optical signals reflected by the measuring object,
wherein the light receiving part receives an optical signal transmitted through the optical filter.

6. A vapor growth method comprising:
loading a substrate to a reaction chamber;
supplying a gas to the reaction chamber;
heaing the substrate from a surface opposite to a film growth surface of the substrate;
rotating the substrate via a susceptor by a rotation part;
controlling a flow rate of a purge gas into the rotation part;
emitting an optical signal to a measuring object;
receiving the optical signal reflected by the measuring object;
determining whether a light receiving position of the optical signal is out of a predetermined first light receiving range; and
reducing a supply amount of the purge gas when a swing of an output of the optical signal is detected.

7. The position deviation detection method according to claim 6, comprising:
eliminating, by an optical filter, a wavelength component other than a wavelength component of the emitted optical signal among optical signals reflected by the measuring object,
wherein an optical signal transmitted through the optical filter is received.
